(19) United States
(12) Patent Application Publication
(10) Pub. No.: US 2009/0165845 A1
(43) Pub. Date: Jul. 2, 2009

(54) BACK CONTACT MODULE FOR SOLAR CELL

(75) Inventors: Fu-Chun Tsao, Taoyuan County (TW); Chi-Lin Chen, Hsinchu County (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(73) Assignee: INDUSTRIAL TECHNOLOGY RESEARCH INSTITUTE, Hsinchu (TW)

(21) Appl. No.: 12/055,305

(22) Filed: Mar. 25, 2008

(30) Foreign Application Priority Data
Dec. 27, 2007 (TW) 96150581

(51) Int. Cl. H01L 31/04; H01L 31/18

(52) U.S. Cl. 136/256; 438/98; 257/E31.11

(57) ABSTRACT

A back contact module for a solar cell is provided. The back contact module includes a transparent conductive layer, a plurality of nano-sized scatters in the transparent conductive layer, and a metal layer on the transparent conductive layer.

### CROSS-REFERENCE TO RELATED APPLICATION

This application claims the priority benefit of Taiwan application serial no. 96150581, filed on Dec. 27, 2007. The entirety the above-mentioned patent application is hereby incorporated by reference herein and made a part of specification.

### BACKGROUND OF THE INVENTION

1. Field of the Invention

The present invention generally relates to a back contact module for a thin-film solar cell.

2. Description of Related Art

Solar energy is a renewable and environment-protected energy that attracts the most attention for solving the problems of the shortage and pollution of petrochemical energies. Solar cells capable of directly converting solar energy into electric energy have become the significant topic in research.

The basic structure of a typical solar cell includes four major portions, i.e., a substrate, P-N diode, an antireflective coating, and two metal electrodes, and works on the principle of photovoltaic effect. In brief, the substrate is the main body of the solar cell, the P-N diode is the source of the photovoltaic effect, the antireflective coating reduces the reflection of the incident light to improve the photocurrent, and the metal electrode connects elements and an external load. When sunlight is incident through a glass substrate, a carrier-depletion region formed on the P-N junction absorbs the sunlight and generates electron-hole pairs. Since the P-type and N-type semiconductors carry the negative and positive charges respectively, a built-in electric field forces the electron-hole pairs to be apart, such that the electrons drift towards N-type region, while the holes drift towards P-type region. Thus, a drifting current from N-type region to P-type region is generated, which is referred to as the photocurrent. The generated photocurrent may be utilized after being transferred to the load through the metal electrodes.

Generally speaking, the electrodes in the solar cell module are respectively disposed on surfaces with and without irradiation for external connection. The electrode on the surface without irradiation is generally formed by coating a back surface field (BSF) metal layer entirely on the surface without irradiation. The BSF metal layer can enhance the collecting of carriers, and recycle the unabsorbed photons. The electrode on the surface with irradiation effectively collects carriers and meanwhile reduces the ratio of incident light shielded by the metal lines as much as possible. Thus, a row of fine finger-shaped metal electrodes extend from the strip metal electrode. A material of the metal electrodes of the solar cell is generally an alloy of aluminum and other metals. However, in a thin film solar cell, in order to meet the monolithism requirements, the metal electrode on the surface with irradiation is made of a transparent conductive oxide (TCO).

In addition to semiconductor, Schottky diode formed by metal-semiconductor contact, metal-insulator-semiconductor having a structure similar to the metal-oxide-semiconductor (MOS), organic matters, or polymers may also be used as the photoelectric conversion layer for the solar cell. Furthermore, the solar cell can work not depending on the photovoltaic effect, and the photoelectric chemical effect of dye-sensitized solar cell can also generate a voltage after irradiation.

In fact, during the photoelectric conversion, not all the incident light spectrum is absorbed by the solar cell and converted into the current. About a half of the spectrum has no contribution to the output of the cell due to the low energy (lower than the bandgap of the semiconductor). And, a half of energy of the absorbed photons in the other half of the spectrum is released in the form of heat, except the energy required for generating the electron-hole pairs. Therefore, the maximal efficiency of a single cell is about 25%.

Therefore, in order to improve the efficiency of the solar cell, some studies suggest increasing the thickness of the photoelectric conversion layer to increase the propagation path of the incident light. However, some materials of the photoelectric conversion layer are very expensive and are formed slowly, thus significantly increasing the material cost and the process time.

Another method performs a textured surface treatment on the electrode material to generate a rough surface, so as to scatter the light rays, thus reducing the reflection of the incident light and increasing the propagation distance of the incident light in the photoelectric conversion layer. However, such manner can only increase the scattering of the short-wavelength light, thus having limited effect on improving the efficiency of the solar cell. Patents related to this method include U.S. Pat. No. 4,694,116 or 6,787,692.

Further, WO 2005/076370 set forth a back contact, which adopts a transparent conductive layer to replace the conventional Al, Ag, Mo, or Cu electrode, and uses the white dielectric pigment to achieve the reflection of the light, thereby improving the light capturing efficiency. However, the transparent conductive layer in the structure has a large thickness, and the effect on improving the efficiency of the solar cell is limited.

### SUMMARY OF THE INVENTION

Accordingly, the present invention is directed to a back contact module, capable of enhancing the scattering of the long-wavelength light to extend the propagation path of the incident light and the reflected light in the photoelectric conversion layer, so as to improve the efficiency of the solar cell.

The present invention is directed to a method of manufacturing a back contract module, which can improve the efficiency of the solar cell, reduce the material cost, and reduce the process time.

The present invention provides a back contact module for a solar cell, which includes a transparent conductive layer, a plurality of nano-sized scatters in the transparent conductive layer, and a first metal layer on the transparent conductive layer.

The present invention further provides a method of manufacturing a back contact module for a solar cell. The method includes forming a transparent conductive layer, and forming a plurality of nano-sized scatters in the transparent conductive layer, and forming a first metal layer on the transparent conductive layer.

In the present invention, the nano-sized scatters are formed to enhance the scattering of long-wavelength light, extend the propagation path of the incident light and the reflected light in the photoelectric conversion layer, so as to improve the efficiency of the solar cell, reduce the material cost, and reduce the process time.

In order to make the features and advantages of the present invention more clear and understandable, the following embodiments are illustrated in detail with reference to the appended drawings.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1A is a schematic cross-sectional view of a back contact module for a solar cell according to an embodiment of the present invention.

FIG. 1B is a schematic cross-sectional view of another back contact module for a solar cell according to another embodiment of the present invention.

FIGS. 2A to 2B or 2B-1 are schematic cross-sectional views of a manufacturing process of a back contact module for a solar cell according to an embodiment of the present invention.

FIGS. 3A to 3C or 3C-1 are schematic cross-sectional views of a manufacturing process of another back contact module for a solar cell according to another embodiment of the present invention.

FIGS. 4A to 4B or 4B-1 are schematic cross-sectional views of a manufacturing process of another back contact module for a solar cell according to another embodiment of the present invention.

FIG. 5 shows a scanning electron microscope (SEM) diagram of an Ag layer on an Asahi glass substrate after performing an annealing process according to an experiment of the present invention.

FIG. 6 is a diagram of haze vs. wavelength for a glass substrate, an Ag layer on a Asahi glass substrate and an Ag layer on an Asahi glass substrate after performing an annealing process according to another experiment of the present invention.

FIG. 7 is a diagram of haze vs. wavelength for a AZO film and an Ag layer on a AZO film after performing an annealing process according to still another experiment of the present invention.

### DESCRIPTION OF THE EMBODIMENTS

Reference will now be made in detail to the present embodiments of the invention, examples of which are illustrated in the accompanying drawings. Wherever possible, the same reference numbers are used in the drawings and the description to refer to the same or like parts.

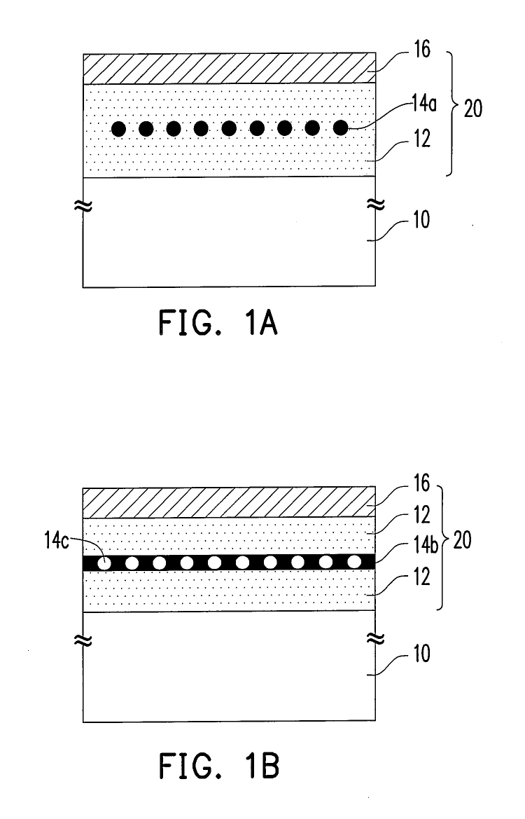

FIGS. 1A and 1B are schematic cross-sectional views of a back contact module for a solar cell according to embodiments of the present invention respectively.

Referring to FIG. 1A, a back contact module 20 for a solar cell is disposed on a photoelectric conversion layer 10, and includes a transparent conductive layer 12, a metal layer 16, and a plurality of nano-sized scatters 14a in the transparent conductive layer 12. A material of the transparent conductive layer 12 is, for example, a transparent conductive oxide, such as indium tin oxide (ITO), fluorine doped tin oxide (FTO), aluminium doped zinc oxide (AZO), gallium doped zinc oxide (GZO), or a combination thereof. A material of the metal layer 16 is, for example, Al, Ag, Mo, or Cu. The nano-sized scatters 14a may be nano-sized metal single particles, nano-sized metal clusters, or a combination thereof, and a size of the nano-sized scatters is tens of nanometers to hundreds of nanometer. A material of the nano-sized metal single particles or the nano-sized metal clusters has a refractive index difference of 0.1 or more relative to the transparent conductive layer 12, and includes, for example, Au, Ag, Al, Sn, Ni, Pt, Ti, V, Mo, W, In, or a combination thereof.

Referring to FIG. 1B, a back contact module 20 for a solar cell is disposed on the photoelectric conversion layer 10, and includes a transparent conductive layer 12, a metal layer 16, and a metal layer 14b in the transparent conductive layer 12. A material of the transparent conductive layer 12 is, for example, a transparent conductive oxide, such as ITO, FTO, AZO, GZO, or a combination thereof. A material of the metal layer 16 is, for example, Al, Ag, Mo, or Cu. The metal layer 14b may be a metal film. The metal layer 14b has a plurality of nano-sized holes 14c serving as nano-sized scatters. A size of the nano-sized holes 14c is, for example, tens of nanometers to hundreds of nanometers. Herein, the metal layer 14b may also be a plurality of nano-sized metal single particles, a plurality of metal clusters, or a combination thereof. The nano-sized holes 14c are gaps between the nano-sized metal single particles, gaps between the nano-sized metal clusters, or gaps between the nano-sized metal single particles and the nano-sized metal clusters, or a combination thereof. A material of the metal layer 14b has a refractive index difference of 0.1 or more relative to the transparent conductive layer 12, and includes, for example, Au, Ag, Al, Sn, Ni, Pt, Ti, V, Mo, W, In, or a combination thereof.

The present invention has a plurality of scatters formed in the transparent conductive layer of the back contact module, so as to enhance the scattering of long-wavelength (for example, 650-800 nm) light and extend the propagation path of the incident light and the reflected light in the photoelectric conversion layer, such that the light can be effectively absorbed by the photoelectric conversion layer, thereby greatly improving the efficiency of the solar cell.

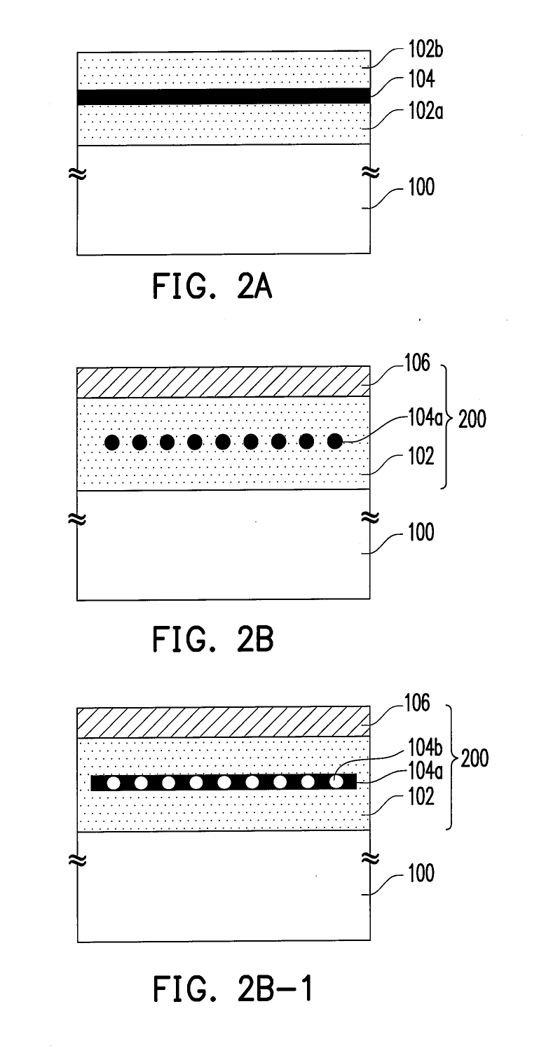

FIGS. 2A to 2B or 2B-1 are schematic cross-sectional views of a manufacturing process of a back contact module for a solar cell according to an embodiment of the present invention.

Referring to FIG. 2A, a transparent conductive sub-layer 102a is formed on a photoelectric conversion layer 100 of the solar cell. A material of the transparent conductive sub-layer 102a is, for example, a transparent conductive oxide, such as ITO, FTO, AZO, GZO, or a combination thereof. The method of forming the transparent conductive sub-layer 102a is, for example, chemical vapor deposition (CVD), sputtering method, or other suitable methods.

Next, a metal layer 104 is formed on the transparent conductive sub-layer 102a. A material of the metal layer 104 has a refractive index difference of 0.1 or more relative to the transparent conductive sub-layer 102a, and includes, for example, Au, Ag, Al, Sn, Ni, Pt, Ti, V, Mo, W, In, or a combination thereof. The method of forming the metal layer 104 is, for example, sputtering method or other suitable methods. Thereafter, another transparent conductive sub-layer 102b is formed on the transparent conductive sub-layer 102a. A material of the transparent conductive sub-layer 102b is, for example, a transparent conductive oxide, such as ITO, FTO, AZO, GZO, or combination thereof. The method of forming the transparent conductive sub-layer 102b is, for example, CVD, sputtering method, or other suitable methods.

Then, referring to FIGS. 2B and 2B-1, an annealing process is performed. A temperature of the annealing process is, for example, 100 degrees Celsius (° C.) to 200° C. In an embodiment, an annealing process is performed to make the metal of the metal layer 104 self-clustering so as to form a plurality of nano-sized metal single particles, a plurality of metal clusters 104a, or a combination thereof, which are covered by the transparent conductive layer 102 formed by the combination of the transparent conductive sub-layers 102a and 102b. The nano-sized metal single particles, the plurality of nano-sized metal clusters 104a, or a combination thereof serve as the nano-sized scatters, as shown in FIG. 2B. In another embodiment, referring to FIG. 2B-1, an annealing process is performed to make the metal of the metal layer 104 self-clustering so as to form a plurality of nano-sized metal single particles, a plurality of metal clusters 104a, or a combination thereof, or to form another metal film. The transparent conductive sub-layers 102a and 102b are melted to form the transparent conductive layer 102 after the annealing process. However, the gaps 104b generated between the nano-sized metal single particles or the nano-sized metal clusters during the self-clustering are not covered by the transparent conductive layer 102, and thus the gaps 104b are also referred to as nano-sized holes i.e. serve as nano-sized scatters.

Then, a metal layer 106 is formed on the transparent conductive layer 102 to serve as a contact electrode, and thus the manufacturing of the back contact module 200 is completed. A material of the metal layer 106 is, for example, Al, Ag, Mo, or Cu. The method of forming the metal layer 106 is, for example, sputtering method or other suitable methods.

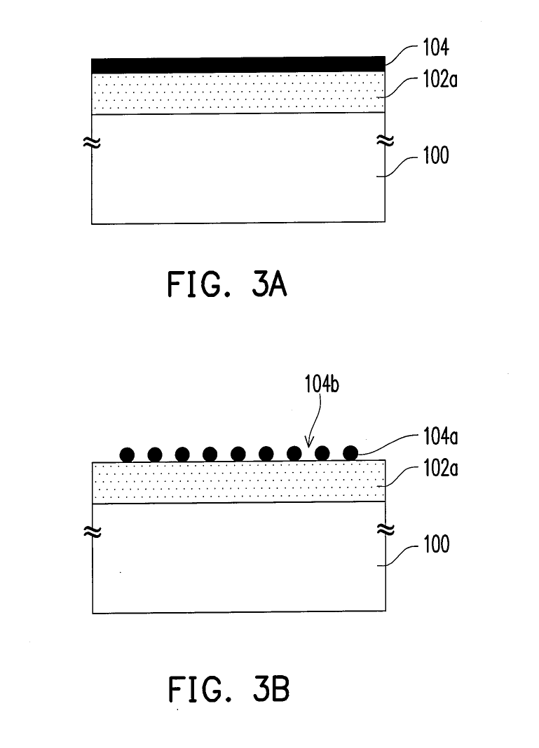

FIGS. 3A to 3C or 3C-1 are schematic cross-sectional views of a manufacturing process of another back contact module for a solar cell according to another embodiment of the present invention.

Referring to FIG. 3A, a transparent conductive sub-layer 102a is formed on a photoelectric conversion layer 100 of the solar cell. A material of the transparent conductive sub-layer 102a is, for example, a transparent conductive oxide, such as ITO, FTO, AZO, GZO, or combination thereof. The method of forming the transparent conductive sub-layer 102a is, for example, CVD, sputtering method, or other suitable methods. Next, a metal layer 104 is formed on the transparent conductive sub-layer 102a. A material of the metal layer 104 has a refractive index difference of 0.1 or more relative to the transparent conductive sub-layer 102a, and includes, for example, Au, Ag, Al, Sn, Ni, Pt, Ti, V, Mo, W, In, or a combination thereof. The method of forming the metal layer 104 is, for example, sputtering method or other suitable methods.

Next, referring to FIG. 3B, an annealing process is performed to make the metal of the metal layer 104 self-clustering so as to form a plurality of metal single particles, a plurality of metal clusters 104a, or a combination thereof, and gaps 104b formed therebetween. A size of the metal single particles or the metal clusters may be at the nanometer-level or larger. A temperature of the annealing process is, for example, 100° C. to 200° C.

Then, referring to FIG. 3C, another transparent conductive sub-layer 102b is formed on the transparent conductive sub-layer 102a and around the nano-sized metal single particles or the nano-sized metal clusters 104a, so as to form the transparent conductive layer 102. A material of another transparent conductive sub-layer 102b is, for example, a transparent conductive oxide, such as ITO, FTO, AZO, GZO, or combination thereof. The method of forming another transparent conductive layer 102b is, for example, CVD, sputtering method, or other suitable methods.

When another transparent conductive sub-layer 102b fills the gaps 104b between the nano-sized metal single particles or the nano-sized metal clusters 104a, the metal single particles, the metal clusters, or a combination thereof serve as the nano-sized scatters, as shown in FIG. 3C. Therefore, when the metal single particles and the metal clusters 104a serve as the nano-sized scatters, the size must be at the nanometer-level and must be about tens of nanometers to hundreds of nanometers.

Referring to FIG. 3C-1, when another formed transparent conductive sub-layer 102b does not fill the gaps 104b between the metal single particles or the metal clusters 104a, the gaps 104b are also referred to as nano-sized holes i.e. serve as nano-sized scatters. Therefore, when the nano-sized scatters are nano-sized holes, the size of the metal single particles or the metal clusters 104a is not limited, but the size of the gaps 104b between the metal single particles or the metal clusters 104a must be controlled to be about 10 nm to 50 nm. Definitely, the metal single particles, the metal clusters 104a, and the gaps 104b therebetween can serve as the nano-sized scatters simultaneously, but the sizes must be controlled at the nanometer-level and must be about tens of nanometers to hundreds of nanometers.

Then, a metal layer 106 is formed on the transparent conductive layer 102 to serve as the contact electrode, and thus the manufacturing of the back contact module 200 is completed. A material of the metal layer 106 is, for example, Al, Ag, Mo, or Cu. The method of forming the metal layer 106 is, for example, sputtering method or other suitable methods.

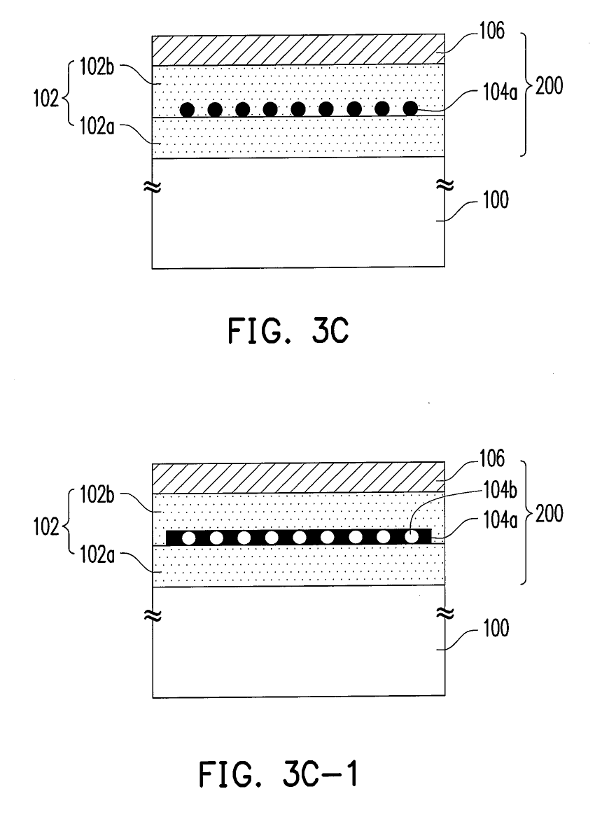

FIGS. 4A to 4B or 4B-1 are schematic cross-sectional views of a manufacturing process of anther back contact module for a solar cell according to another embodiment of the present invention.

Referring to FIG. 4A, a transparent conductive sub-layer 102a is formed on a photoelectric conversion layer 100 of the solar cell. A material of the transparent conductive sub-layer 102a is, for example, a transparent conductive oxide, such as ITO, FTO, AZO, GZO, or combination thereof.

Next, a plurality of metal single particles, a plurality of metal clusters 104a, or a combination thereof having the gaps 104b therebetween is directly formed on the transparent conductive sub-layer 102a. A size of the metal single particles or the metal clusters may be at the nanometer-level or larger. A material of the metal single particles, metal clusters 104a, or a combination thereof has a refractive index difference of 0.1 or more relative to the transparent conductive sub-layer 102a, and includes, for example, Au, Ag, Al, Sn, Ni, Pt, Ti, V, Mo, W, In, or a combination thereof. The method of directly forming a plurality of metal single particles, a plurality of metal clusters, or a combination thereof on the transparent conductive sub-layer 102a is, for example, a spraying or coating method.

Then, referring to FIG. 4B, another transparent conductive sub-layer 102b is formed on the transparent conductive sub-layer 102a and around the nano-sized metal single particles or the nano-sized metal clusters 104a, so as to form the transparent conductive layer 102. A material of another transparent conductive sub-layer 102b is, for example, a transparent conductive oxide, such as ITO, FTO, AZO, GZO, or combination thereof. The method of forming another transparent conductive sub-layer 102b is, for example, CVD, sputtering method, or other suitable methods.

When another transparent conductive sub-layer 102b fills the gaps 104b between the nano-sized metal single particles or the nano-sized metal clusters 104a, the metal single particles, the metal clusters, or a combination thereof serve as the nano-sized scatters, as shown in FIG. 4B. Therefore, when the metal single particles and the metal clusters 104a serve as the nano-sized scatters, the size must be controlled at the nanometer-level and must be about tens of nanometers to hundreds of nanometers when forming the metal single particles and the metal clusters 104a.

Referring to FIG. 4B-1, when another formed transparent conductive sub-layer 102b does not fill the gaps 104b between the metal single particles or the metal clusters 104a, the gaps 104b are also referred to as nano-sized holes i.e. serve as nano-sized scatters. Therefore, when the nano-sized scatters are nano-sized holes, the size of the metal single particles or the metal clusters 104a is not limited, but the size of the gaps 104b between the metal single particles or the metal clusters 104a must be controlled at the nanometer-level and must be about several tens nm to hundreds of nanometers.

Definitely, the metal single particles, the metal clusters 104a, and the gaps 104b therebetween can serve as the nano-sized scatters at the same time, but the sizes must be controlled at the nanometer-level and must be about tens of nanometers to hundreds of nanometers.

Then, a metal layer 106 is formed on the transparent conductive layer 102 to serve as the contact electrode, and thus the manufacturing of the back contact module 200 is completed. A material of the metal layer 106 is, for example, Al, Ag, Mo, or Cu. The method of forming the metal layer 106 is, for example, sputtering method or other suitable methods.

The back contact module 20 of the present invention is applicable to silicon solar cells or dye-sensitized solar cells. Therefore, the photoelectric conversion layer 10 or 100 may be various materials which are applicable to the silicon solar cells or dye-sensitized solar cells.

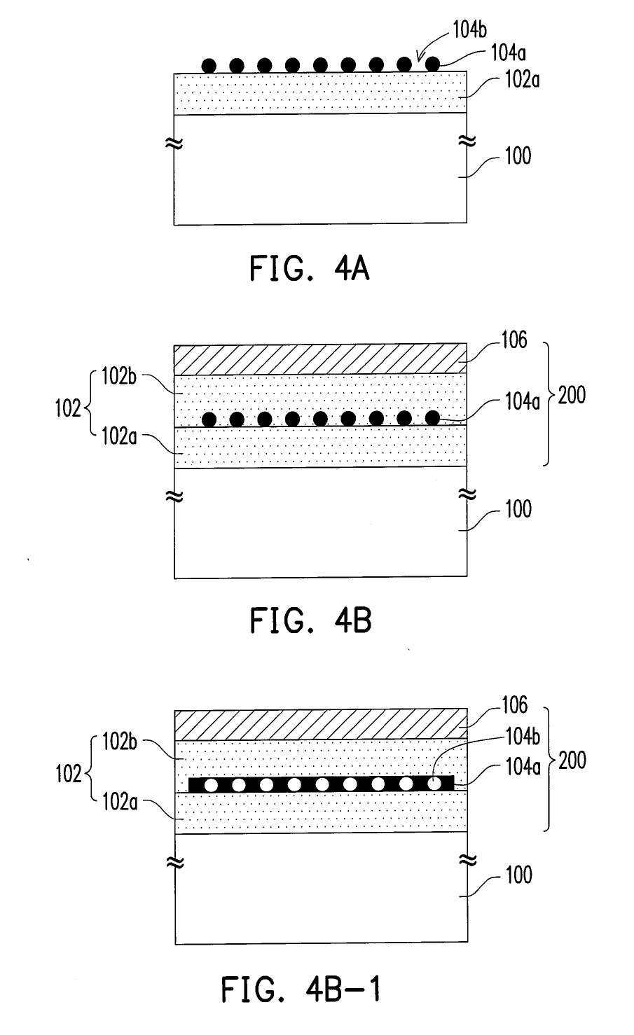

FIG. 5 shows a scanning electron microscope (SEM) diagram of an Ag layer of 20 nm on an Asahi glass substrate after performing an annealing process at 200° C. for 60 minutes. As shown in FIG. 5, after performing the annealing process, nano-sized Ag particles or Ag clusters are formed on the Asahi glass substrate.

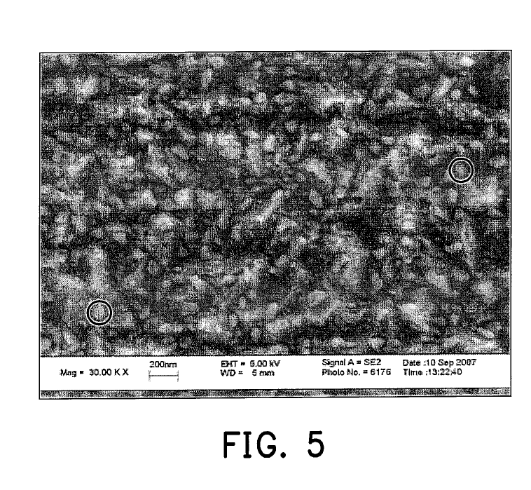

FIG. 6 is a diagram of haze vs. wavelength for a glass substrate, an Ag layer of 20 nm on an Asahi glass substrate and an Ag layer of 20 nm on an Asahi glass substrate after performing an annealing process at 200° C. for 20 minutes using a ASTM D1003-00 standard test method for Haze. As shown in FIG. 6, after performing the annealing process, the haze of the Ag layer on the glass is increased at wavelength range of 500 to 800 nm.

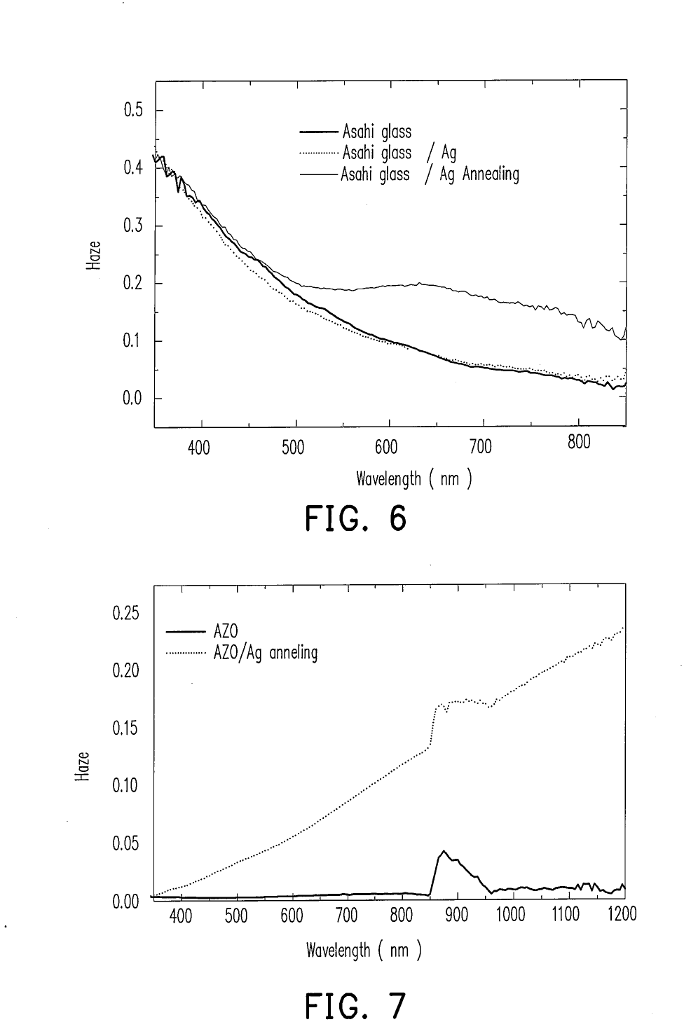

FIG. 7 is a diagram of haze vs. wavelength for a AZO film and an Ag layer of 20 nm on a AZO film after performing an annealing process at 200° C. for 30 minutes using a ASTM D1003-00 standard test method for Haze. As shown in FIG. 7, after performing the annealing process, the haze of the Ag layer on the AZO film is increased at wavelength range of 600 to 1200 nm.

The present invention forms a plurality of scatters in the transparent conductive layer to enhance the scattering of light and increase the propagation path of the incident light and reflected light in the photoelectric conversion layer, so as to improve the efficiency of the solar cell. Thus, the thickness of the photoelectric conversion layer is very thin, and the material cost of the photoelectric conversion layer is reduced and the process time of the photoelectric conversion layer is reduced.

It will be apparent to those skilled in the art that various modifications and variations may be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A back contact module for a solar cell, comprising:
a transparent conductive layer, disposed on a photoelectric conversion layer;
a plurality of nano-sized scatters, disposed in the transparent conductive layer; and
a first metal layer, disposed on the transparent conductive layer.

2. The back contact module for a solar cell according to claim 1, wherein a size of the nano-sized scatters is 10 nm to 50 nm.

3. The back contact module for a solar cell according to claim 1, wherein the nano-sized scatters are a plurality of nano-sized metal single particles, a plurality of nano-sized metal clusters, or a combination thereof.

4. The back contact module for a solar cell according to claim 1, wherein a material of the nano-sized metal single particles or the nano-sized metal clusters has a refractive index difference of 0.1 or more relative to the transparent conductive layer.

5. The back contact module for a solar cell according to claim 4, wherein a material of the nano-sized metal single particles or the nano-sized metal clusters comprises Au, Ag, Al, Sn, Ni, Pt, Ti, V, Mo, W, In, or a combination thereof.

6. The back contact module for a solar cell according to claim 1, wherein the nano-sized scatters are a plurality of nano-sized holes in a second metal layer of the transparent conductive layer, between the plurality of metal single particles, between the plurality of metal clusters, or a combination thereof.

7. The back contact module for a solar cell according to claim 1, wherein a material of the transparent conductive layer comprises indium tin oxide (ITO), fluorine doped tin oxide (FTO), aluminium doped zinc oxide (AZO), gallium doped zinc oxide (GZO), or a combination thereof.

8. A method of manufacturing a back contact module for a solar cell, comprising:
forming a transparent conductive layer;
forming a plurality of nano-sized scatters in the transparent conductive layer; and
forming a first metal layer on the transparent conductive layer.

9. The method of manufacturing a back contact module for a solar cell according to claim 8, wherein the process of forming the transparent conductive layer and the nano-sized scatters comprises:
forming a first transparent conductive sub-layer;
forming a second metal layer on the first transparent conductive sub-layer;
forming a second transparent conductive sub-layer, such that the first transparent conductive sub-layer and the second transparent conductive sub-layer form the transparent conductive layer; and
performing an annealing process, such that metal atoms of the second metal layer are self-clustering to form the nano-sized scatters.

10. The method of manufacturing a back contact module for a solar cell according to claim 9, wherein the nano-sized scatters are nano-sized metal single particles, nano-sized metal clusters, nano-sized holes, or a combination thereof.

11. The method of manufacturing a back contact module for a solar cell according to claim 9, wherein a material of the second metal layer has a refractive index difference of 0.1 or more relative to the transparent conductive layer.

12. The method of manufacturing a back contact module for a solar cell according to claim 11, wherein a material of the second metal layer comprises Au, Ag, Al, Sn, Ni, Pt, Ti, V, Mo, W, In, or a combination thereof.

13. The method of manufacturing a back contact module for a solar cell according to claim 9, wherein the annealing process is performed before forming the second transparent conductive sub-layer.

14. The method of manufacturing a back contact module for a solar cell according to claim 9, wherein the annealing process is performed after forming the second transparent conductive sub-layer.

15. The method of manufacturing a back contact module for a solar cell according to claim 9, wherein the process of forming the transparent conductive layer and the nano-sized scatters comprises:
forming a first transparent conductive sub-layer;
directly forming the nano-sized scatters on the first transparent conductive sub-layer; and
forming a second transparent conductive sub-layer on the nano-sized scatters.

16. The method of manufacturing a back contact module for a solar cell according to claim 15, wherein the process of forming the nano-sized scatters comprises directly forming a plurality of metal single particles, a plurality of metal clusters, or a combination thereof on the first transparent conductive sub-layer.

17. The method of manufacturing a back contact module for a solar cell according to claim 16, wherein the nano-sized scatters are metal single particles, nano-sized metal clusters, or a combination thereof, and a size of the nano-sized scatters being the metal single particles and the nano-sized metal clusters is tens of nanometers to hundreds of nanometers.

18. The method of manufacturing a back contact module for a solar cell according to claim 17, wherein a material of the nano-sized metal single particles or the nano-sized metal clusters has a refractive index difference of 0.1 or more relative to the transparent conductive layer.

19. The method of manufacturing a back contact module for a solar cell according to claim 18, wherein a material of the nano-sized metal single particles or the nano-sized metal clusters comprises Ag, Pt, Pd, Mo, or a combination thereof.

20. The method of manufacturing a back contact module for a solar cell according to claim 16, wherein the nano-sized scatters are a plurality of nano-sized holes, and the nano-sized holes are gaps between the metal single particles and uncovered by the second transparent conductive sub-layer, and gaps between the metal clusters and uncovered by the second transparent conductive sub-layer, or gaps between the metal single particles and the metal clusters and uncovered by the second transparent conductive sub-layer, or a combination thereof, and a size of the gaps is tens of nanometers to hundreds of nanometers.
